(19) United States
(12) Patent Application Publication
(10) Pub. No.: US 2025/0218972 A1
(43) Pub. Date: Jul. 3, 2025

(54) SEMICONDUCTOR SUBSTRATE AND SEMICONDUCTOR EPITAXIAL SUBSTRATE

(71) Applicant: SUMITOMO ELECTRIC INDUSTRIES, LTD., Osaka (JP)

(72) Inventors: Takashi SAKURADA, Osaka (JP); Hideyuki HISANABE, Osaka (JP); Hideto TAMASO, Osaka (JP); Takeru FUKUSHIMA, Osaka (JP); Tsutau YOKOCHO, Osaka (JP); Hirofumi YAMAMOTO, Osaka (JP)

(73) Assignee: SUMITOMO ELECTRIC INDUSTRIES, LTD., Osaka (JP)

(21) Appl. No.: 18/849,789

(22) PCT Filed: Mar. 7, 2023
(86) PCT No.: PCT/JP2023/008554

§ 371 Date: Sep. 23, 2024

(30) Foreign Application Priority Data
Mar. 28, 2022 (JP) 2022-051805

(51) Int. Cl. H01L 23/544; H10D 62/832

(52) U.S. Cl. CPC H01L 23/544; H10D 62/8325

(57) ABSTRACT

A semiconductor substrate has a main surface, a reference mark, and an epitaxial growth suppression film. The reference mark is constituted of a recess formed in the main surface and serves as a reference for an in-plane coordinate. The epitaxial growth suppression film is provided in at least part of inside of the recess. The reference mark has at least two or more reference marks provided in the main surface. The main surface is composed of a semiconductor material. The epitaxial growth suppression film is composed of a material different from the semiconductor material.

### TECHNICAL FIELD

The present disclosure relates to a semiconductor substrate and a semiconductor epitaxial substrate. The present application claims priority based on Japanese Patent Application No. 2022-051805 filed on Mar. 28, 2022. The entire contents of the Japanese Patent Application are incorporated herein by reference.

### BACKGROUND ART

Japanese Patent Laying-Open No. 4-62858 (PTL 1) describes a method of observing and analyzing a foreign matter. In this method, a coordinate system is set by providing a coordinate reference on a wafer.

Japanese Patent Laying-Open No. 2000-269286 (PTL 2) describes a method of specifying a position of a defect of a semiconductor substrate. In this method, the position of the defect is specified based on affine transformation and coordinate values in a coordinate system of a defect evaluation apparatus.

### CITATION LIST

### Patent Literature

PTL 1: Japanese Patent Laying-Open No. 4-62858

PTL 2: Japanese Patent Laying-Open No. 2000-269286

### SUMMARY OF INVENTION

A semiconductor substrate according to the present disclosure includes a main surface, a reference mark, and an epitaxial growth suppression film. The reference mark is constituted of a recess formed in the main surface and serves as a reference for an in-plane coordinate. The epitaxial growth suppression film is provided in at least part of inside of the recess. The reference mark has at least two or more reference marks provided in the main surface. The main surface is composed of a semiconductor material. The epitaxial growth suppression film is composed of a material different from the semiconductor material.

### BRIEF DESCRIPTION OF DRAWINGS

FIG. 1 is a schematic plan view showing a configuration of a semiconductor substrate according to a first embodiment.

FIG. 2 is an enlarged plan view showing a region II of FIG. 1.

FIG. 3 is a schematic cross sectional view along a line III-III of FIG. 2.

FIG. 4 is a schematic cross sectional view showing a configuration of a semiconductor substrate according to a second embodiment.

FIG. 5 is a schematic cross sectional view showing a configuration of a semiconductor substrate according to a third embodiment.

FIG. 6 is a schematic cross sectional view showing a configuration of a semiconductor epitaxial substrate according to a fourth embodiment.

FIG. 7 is a schematic cross sectional view showing a configuration of a semiconductor epitaxial substrate according to a fifth embodiment.

FIG. 8 is a schematic cross sectional view showing a configuration of a semiconductor epitaxial substrate according to a sixth embodiment.

FIG. 9 is a schematic cross sectional view showing a configuration of a semiconductor epitaxial substrate according to a seventh embodiment.

FIG. 10 is a schematic cross sectional view showing a configuration of a semiconductor epitaxial substrate according to an eighth embodiment.

FIG. 11 is a schematic plan view showing a configuration of a semiconductor epitaxial substrate according to a ninth embodiment.

FIG. 12 is an enlarged plan view showing a region XII in FIG. 11.

FIG. 13 is a schematic cross sectional view along a line XIII-XIII of FIG. 12.

FIG. 14 is a schematic cross sectional view showing a configuration of a semiconductor epitaxial substrate according to a tenth embodiment.

FIG. 15 is a schematic cross sectional view showing a configuration of a semiconductor epitaxial substrate according to an eleventh embodiment.

FIG. 16 is a schematic cross sectional view showing a configuration of a semiconductor epitaxial substrate according to a twelfth embodiment.

FIG. 17 is a schematic cross sectional view showing a configuration of a semiconductor epitaxial substrate according to a thirteenth embodiment.

FIG. 18 is a schematic cross sectional view showing a configuration of a semiconductor epitaxial substrate according to a fourteenth embodiment.

FIG. 19 is a schematic cross sectional view showing a configuration of a semiconductor epitaxial substrate according to a fifteenth embodiment.

FIG. 20 is a schematic cross sectional view showing a configuration of a semiconductor epitaxial substrate according to a sixteenth embodiment.

FIG. 21 is a flowchart schematically showing a first method of manufacturing the semiconductor substrate according to the second embodiment.

FIG. 22 is a schematic cross sectional view showing a step of preparing a semiconductor base material.

FIG. 23 is a schematic sectional view showing a step of applying a resist.

FIG. 24 is a schematic cross sectional view showing a step of forming an opening by photolithography.

FIG. 25 is a schematic cross sectional view showing a step of etching the semiconductor base material in the opening.

FIG. 26 is a first schematic cross sectional view showing a step of forming an epitaxial growth suppression film.

FIG. 27 is a flowchart schematically showing a second method of manufacturing the semiconductor substrate according to the second embodiment.

FIG. 28 is a second schematic cross sectional view showing a step of forming an epitaxial growth suppression film.

FIG. 29 is a flowchart schematically showing a third method of manufacturing the semiconductor substrate according to the second embodiment.

FIG. 30 is a schematic cross sectional view showing a step of performing laser processing onto the semiconductor base material.

FIG. 31 is a flowchart schematically showing a fourth method of manufacturing the semiconductor substrate according to the second embodiment.

### DETAILED DESCRIPTION

### Problem to be Solved by the Present Disclosure

An object of the present disclosure is to provide a semiconductor substrate and a semiconductor epitaxial substrate so as to suppress deterioration of visibility of a reference mark.

### Advantageous Effect of the Present Disclosure

According to the present disclosure, a semiconductor substrate and a semiconductor epitaxial substrate are provided to suppress deterioration of visibility of a reference mark.

### Summary of Embodiments of the Present Disclosure

First, summary of embodiments of the present disclosure will be described.

(1) A semiconductor substrate 100 according to the present disclosure includes a main surface 1, a reference mark 3, and an epitaxial growth suppression film 30. Reference mark 3 is constituted of a recess 24 formed in main surface 1 and serves as a reference for an in-plane coordinate. Epitaxial growth suppression film 30 is provided in at least part of inside of recess 24. Reference mark 3 has at least two or more reference marks provided in main surface 1. Main surface 1 is composed of a semiconductor material. Epitaxial growth suppression film 30 is composed of a material different from the semiconductor material.

(2) In semiconductor substrate 100 according to (1), a depth of recess 24 may be more than 0.5 μm and less than 100 μm.

(3) In semiconductor substrate 100 according to (1) or (2), recess 24 may be constituted of a side surface 22 and a bottom surface 23 contiguous to side surface 22. Epitaxial growth suppression film 30 may be in contact with bottom surface 23.

(4) In semiconductor substrate 100 according to (1) or (2), recess 24 may be constituted of a side surface 22 and a bottom surface 23 contiguous to side surface 22. Epitaxial growth suppression film 30 may be in contact with each of side surface 22 and bottom surface 23. A depression may be formed by epitaxial growth suppression film 30.

(5) In semiconductor substrate 100 according to (1) or (2), recess 24 may be filled with epitaxial growth suppression film 30.

(6) In semiconductor substrate 100 according to any one of (1) to (5), epitaxial growth suppression film 30 may be composed of a material including boron, carbon, nitrogen, or oxygen and having a melting point of 1700° C. or more.

(7) In semiconductor substrate 100 according to any one of (1) to (5), epitaxial growth suppression film 30 may be composed of a material including titanium, zirconium, hafnium, vanadium, niobium, tantalum, chromium, molybdenum, tungsten, magnesium, yttrium, aluminum, nickel, zinc, or gallium.

(8) In semiconductor substrate 100 according to any one of (1) to (7), the semiconductor material may be silicon carbide.

(9) In semiconductor substrate 100 according to any one of (1) to (8), a thickness of epitaxial growth suppression film 30 may be 0.25 times or more as large as a depth of recess 24.

(10) A semiconductor epitaxial substrate 200 according to the present disclosure may include: semiconductor substrate 100 according to any one of (1) to (9); a semiconductor layer 90 formed on epitaxial growth suppression film 30; and an epitaxial layer 40 provided on at least a portion of main surface 1. A thickness of epitaxial layer 40 may be larger than a minimum value of a thickness of semiconductor layer 90.

(11) A semiconductor epitaxial substrate 200 according to the present disclosure may include: semiconductor substrate 100 according to any one of (1) to (9); semiconductor substrate 100 according to any one of (1) to (9); and an epitaxial layer 40 provided on at least a portion of main surface 1. Epitaxial layer 40 may not be formed on epitaxial growth suppression film 30.

(12) A semiconductor epitaxial substrate 200 according to the present disclosure includes a semiconductor base material 105, a first epitaxial layer 71, a main surface 5, a reference mark 3, and an epitaxial growth suppression film 30. First epitaxial layer 71 is provided on semiconductor base material 105. Main surface 5 is formed by first epitaxial layer 71. Reference mark 3 is constituted of a recess 24 formed in main surface 5 and serves as a reference for an in-plane coordinate. Epitaxial growth suppression film 30 is provided in at least part of inside of recess 24. Reference mark 3 has at least two or more reference marks provided in main surface 5. Main surface 5 is composed of a semiconductor material. Epitaxial growth suppression film 30 is composed of a material different from the semiconductor material.

(13) Semiconductor epitaxial substrate 200 according to (12) may include: a semiconductor layer 90 formed on epitaxial growth suppression film 30; and a second epitaxial layer 72 provided on at least a portion of main surface 5. A thickness of second epitaxial layer 72 may be larger than a minimum value of a thickness of semiconductor layer 90.

(14) Semiconductor epitaxial substrate 200 according to (12) includes a second epitaxial layer 72 provided on at least a portion of main surface 5. Second epitaxial layer 72 may not be formed on epitaxial growth suppression film 30.

### Details of Embodiments of the Present Disclosure

Hereinafter, embodiments of the present disclosure (hereinafter, also referred to as the present embodiment) will be described in detail with reference to figures. It should be noted that in the below-described figures, the same or corresponding portions are denoted by the same reference characters and will not be described repeatedly. Regarding crystallographic indications in the present specification, an individual orientation is represented by [ ], a group orientation is represented by <>, and an individual plane is represented by () and a group plane is represented by { }. In addition, a negative index is supposed to be crystallographically indicated by putting “-” (bar) above a numeral, but is indicated by putting the negative sign before the numeral in the present specification.

### First Embodiment

First, a configuration of a semiconductor substrate 100 according to a first embodiment will be described.

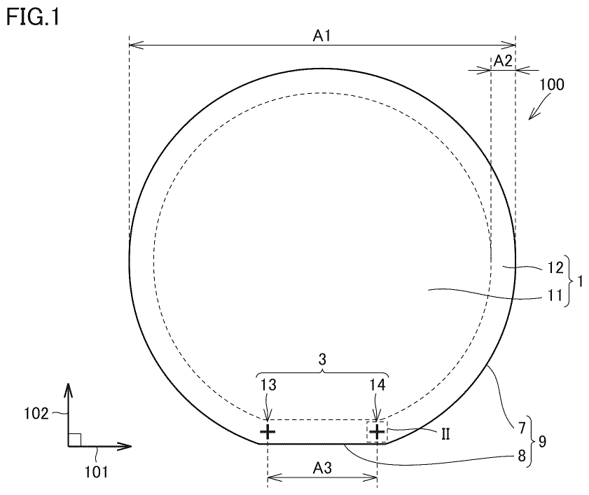

FIG. 1 is a schematic plan view showing the configuration of semiconductor substrate 100 according to the first embodiment. As shown in FIG. 1, semiconductor substrate 100 according to the first embodiment mainly has a first main surface 1 and an outer peripheral edge 9. When viewed in a direction perpendicular to first main surface 1, first main surface 1 is surrounded by outer peripheral edge 9. First main surface 1 is constituted of a first central region 11 and a first outer peripheral region 12. First outer peripheral region 12 is a region within 5 mm from outer peripheral edge 9. First central region 11 is surrounded by first outer peripheral region 12. In a radial direction of first main surface 1, a spacing A2 is 5 mm between outer peripheral edge 9 and a boundary between first central region 11 and first outer peripheral region 12.

Outer peripheral edge 9 has, for example, an orientation flat 8 and an arc-shaped portion 7. Orientation flat 8 extends along a first direction 101. As shown in FIG. 1, orientation flat 8 is in the form of a straight line when viewed in the direction perpendicular to first main surface 1. Arc-shaped portion 7 is contiguous to orientation flat 8. Arc-shaped portion 7 has an arc shape when viewed in the direction perpendicular to first main surface 1.

As shown in FIG. 1, when viewed in the direction perpendicular to first main surface 1, first main surface 1 is expanded along each of first direction 101 and a second direction 102. When viewed in the direction perpendicular to first main surface 1, second direction 102 is a direction perpendicular to first direction 101.

A maximum diameter A1 of first main surface 1 is, for example, 100 mm (4 inches) or more. It should be noted that maximum diameter A1 of first main surface 1 may be 150 mm (6 inches) or more, or may be 200 mm (8 inches) or more. Maximum diameter A1 of first main surface 1 is not particularly limited, and may be, for example, 400 mm (16 inches) or less. Maximum diameter A1 of first main surface 1 is the longest straight-line distance between two different points on outer peripheral edge 9.

It should be noted that in the present specification, 4 inches mean 100 mm or 101.6 mm (4 inches×25.4 mm/inch). 6 inches mean 150 mm or 152.4 mm (6 inches×25.4 mm/inch). 8 inches mean 200 mm or 203.2 mm (8 inches×25.4 mm/inch). 16 inches mean 400 mm or 406.4 mm (16 inches×25.4 mm/inch).

As shown in FIG. 1, semiconductor substrate 100 has a reference mark 3. Reference mark 3 has at least two or more reference marks provided in first main surface 1. As shown in FIG. 1, for example, two reference marks 3 are provided in first outer peripheral region 12. Each of two or more reference marks 3 serves as a reference in two-dimensional position coordinates. As shown in FIG. 1, each of two or more reference marks 3 may be located in a region (first outer peripheral region 12) within 5 mm from the orientation flat when viewed in the direction perpendicular to first main surface 1. The number of reference marks 3 is not particularly limited, and may be, for example, three or more or four or more.

As shown in FIG. 1, a distance A3 between two reference marks 3 is, for example, 30 mm or more when viewed in the direction perpendicular to first main surface 1. Distance A3 between two reference marks 3 is not particularly limited, and may be, for example, 40 mm or more or 50 mm or more. Distance A3 between two reference marks 3 is not particularly limited, and may be, for example, 200 mm or less or 150 mm or less.

As shown in FIG. 1, each of two or more reference marks 3 may have a cross shape when viewed in the direction perpendicular to first main surface 1. Two or more reference marks 3 have, for example, a first reference mark 13 and a second reference mark 14. Distance A3 between first reference mark 13 and second reference mark 14 is a distance from the center of first reference mark 13 to the center of second reference mark 14.

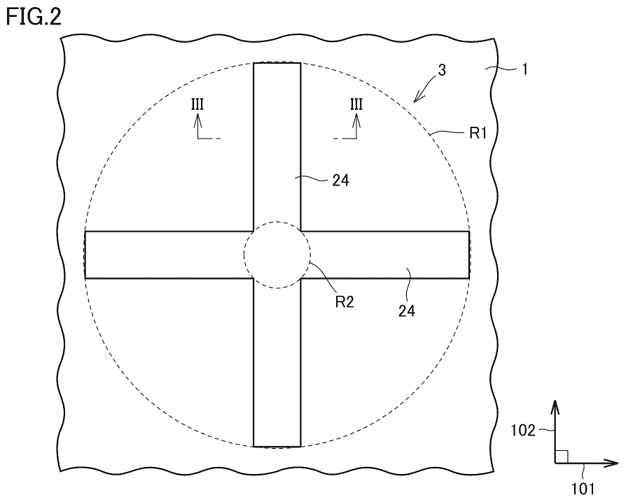

FIG. 2 is an enlarged plan view showing a region II of FIG. 1. As shown in FIG. 2, reference mark 3 is constituted of a recess 24 formed in first main surface 1 and serves as a reference for an in-plane coordinate. When viewed in the direction perpendicular to first main surface 1, the shape of reference mark 3 is, for example, axisymmetric. The shape of reference mark 3 is, for example, a cross shape. For example, two recesses 24 may be provided to intersect perpendicularly at the center thereof. Reference mark 3 may be formed by a single recess 24, or may be formed by a plurality of recesses 24 such as a collection of processing marks, for example.

The shape of reference mark 3 is not limited to the cross shape. The shape of reference mark 3 may be a polygonal shape, an axisymmetric quadrangular (rectangular or square) shape, or a circular shape. Reference mark 3 has a shape that can be surrounded by an imaginary circle, for example. A minimum imaginary circle surrounding reference mark 3 is, for example, a circle circumscribed around reference mark 3. The center of reference mark 3 is the center of the circumscribed circle.

When viewed in the direction perpendicular to first main surface 1, the radius of the minimum imaginary circle (first imaginary circle R1) surrounding each of the plurality of reference marks 3 is, for example, more than 10 μm and less than 3 mm. The radius of first imaginary circle R1 is not particularly limited, and may be, for example, 50 μm or more or 100 μm or more. The radius of first imaginary circle R1 is not particularly limited, and may be, for example, 1 mm or less or 0.5 mm or less.

As shown in FIG. 2, a maximum imaginary circle (second imaginary circle R2) surrounded by reference mark 3 is, for example, a circle inscribed in reference mark 3. The center of the circle inscribed in reference mark 3 may coincide with the center of the circle circumscribed around reference mark 3. When viewed in the direction perpendicular to first main surface 1, the radius of second imaginary circle R2 is, for example, less than 15 μm.

Reference mark 3 serves as a reference for an in-plane coordinate. A straight line passing through the center of first reference mark 13 and the center of second reference mark 14 is defined as an X axis. A straight line parallel to first main surface 1 and perpendicular to the X axis is defined as a Y axis. An intermediate position between the center of first reference mark 13 and the center of second reference mark 14 is defined as the origin of the two-dimensional position coordinates, for example. A direction from the origin toward first reference mark 13 is defined as, for example, a negative direction in the X axis. A direction from the origin toward second reference mark 14 is defined as, for example, a positive direction in the X axis. A direction from the origin toward orientation flat 8 is defined as, for example, a negative direction in the Y axis. A direction opposite to the direction from the origin toward orientation flat 8 is defined as, for example, a positive direction in the Y axis. As described above, the imaginary two-dimensional position coordinate system is determined based on first reference mark 13 and second reference mark 14, for example.

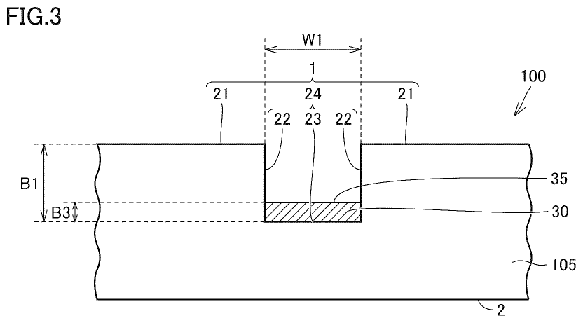

FIG. 3 is a schematic cross sectional view along a line III-III of FIG. 2. As shown in FIG. 3, semiconductor substrate 100 according to the first embodiment has a semiconductor base material 105 and an epitaxial growth suppression film 30. Semiconductor base material 105 has first main surface 1 and a second main surface 2. Second main surface 2 is located opposite to first main surface 1. Recess 24 is provided to be opened at first main surface 1. Recess 24 is constituted of a first side surface 22 and a first bottom surface 23. First bottom surface 23 is contiguous to first side surface 22. First main surface 1 has a first flat surface 21. First side surface 22 is contiguous to first flat surface 21. First flat surface 21 may be parallel to second main surface 2. In a thickness direction of semiconductor base material 105, first bottom surface 23 of recess 24 is located between first flat surface 21 and second main surface 2.

Semiconductor base material 105 is composed of a semiconductor material. The semiconductor material is, for example, silicon carbide (SiC). The semiconductor material may be a semiconductor other than silicon carbide. The semiconductor material may be, for example, gallium arsenide (GaAs), indium phosphide (InP), gallium nitride (GaN), gallium oxide (Ga₂O₃), diamond, or the like. Each of first main surface 1 and second main surface 2 is composed of the semiconductor material.

When semiconductor base material 105 is composed of silicon carbide, semiconductor base material 105 may be a conductive substrate or a semi-insulating substrate. When semiconductor base material 105 is a conductive substrate, the polytype of silicon carbide may be 4H. When semiconductor base material 105 is a semi-insulating substrate, the polytype of silicon carbide may be 4H or 6H. The thickness of semiconductor base material 105 is, for example, 350 μm or more and 500 μm or less. Semiconductor base material 105 includes an n type impurity such as nitrogen (N), for example. The conductivity type of semiconductor base material 105 is, for example, n type.

When semiconductor base material 105 is composed of hexagonal silicon carbide, first direction 101 is, for example, a <11-20> direction. First direction 101 may be, for example, a [11-20] direction. First direction 101 may be a direction obtained by projecting the <11-20> direction onto first main surface 1. From another viewpoint, it can be said that first direction 101 may be a direction including a <11-20> direction component, for example.

Second direction 102 is, for example, a <1-100> direction. Second direction 102 may be, for example, a [1-100] direction. Second direction 102 may be, for example, a direction obtained by projecting the <1-100> direction onto first main surface 1. From another viewpoint, it can be said that second direction 102 may be a direction including a <1-100> direction component, for example.

First main surface 1 may be a {0001} plane or a plane inclined with respect to the {0001} plane. When first main surface 1 is inclined with respect to the {0001} plane, an inclination angle (off angle) thereof with respect to the {0001} plane is, for example, 1° or more and 8° or less. When first main surface 1 is inclined with respect to the {0001} plane, an inclination direction (off direction) of first main surface 1 is, for example, the <11-20> direction.

Epitaxial growth suppression film 30 is provided in at least part of inside of recess 24. Epitaxial growth suppression film 30 is in contact with first bottom surface 23, for example. Epitaxial growth suppression film 30 may be in contact with a portion of first side surface 22.

Epitaxial growth suppression film 30 is composed of a material different from the semiconductor material of first main surface 1 of semiconductor base material 105. A lattice constant of the material of epitaxial growth suppression film 30 is different from a lattice constant of the semiconductor material. The material of epitaxial growth suppression film 30 may be amorphous or polycrystalline. Desirably, the material of epitaxial growth suppression film 30 is not decomposed in a temperature range in which the semiconductor material is formed by epitaxial growth. The melting point of the material of epitaxial growth suppression film 30 is, for example, 1700° C. or more.

The melting point of the material of epitaxial growth suppression film 30 is not particularly limited, and may be, for example, 2000° C. or more, 2500° C. or more, or 3000° C. or more. The melting point of the material of epitaxial growth suppression film 30 is not particularly limited, and may be, for example, 4500° C. or less, 4000° C. or less, or 3500° C. or less. In particular, when the semiconductor layer is SiC, epitaxial growth takes place at a high temperature of about 1600° C., so that a higher melting point of the material of epitaxial growth suppression film 30 is more preferable.

The material of epitaxial growth suppression film 30 includes, for example, boron, carbon, nitrogen, or oxygen. The material of epitaxial growth suppression film 30 is, for example, graphite, diamond, silicon dioxide (SiO₂), silicon nitride (Si₃N₄), or boron nitride (BN). The melting points of graphite, diamond, silicon dioxide, silicon nitride and boron nitride are 3700° C. or more and 4300° C. or less, 3548° C., 1732° C., 1900° C., and 2700° C., respectively.

Epitaxial growth suppression film 30 may be composed of a material including a metal element such as titanium (Ti), zirconium (Zr), hafnium (Hf), vanadium (V), niobium (Nb), tantalum (Ta), chromium (Cr), molybdenum (Mo), tungsten (W), magnesium (Mg), yttrium (Y), aluminum (Al), nickel (Ni), zinc (Zn), or gallium (Ga). Specifically, epitaxial growth suppression film 30 is an oxide, nitride, carbide, or boride of the metal element, or a compound of another element.

A depth (first depth B1) of recess 24 may be more than 0.5 μm and less than 100 μm, for example. First depth B1 is not particularly limited, and may be more than 1 μm or may be more than 10 μm, for example. First depth B1 is not particularly limited, and may be less than 90 μm or may be less than 80 μm, for example. First depth B1 is a distance between first bottom surface 23 and first flat surface 21 in the thickness direction of semiconductor base material 105.

The shape of recess 24 may be, for example, a forward tapered shape. Specifically, the width of recess 24 may be increased in a direction from first main surface 1 toward second main surface 2. The shape of recess 24 may be an inverse tapered shape. Specifically, the width of recess 24 may be decreased in the direction from first main surface 1 toward second main surface 2. First side surface 22 of recess 24 may be perpendicular to first bottom surface 23 of recess 24.

A thickness (third thickness B3) of epitaxial growth suppression film 30 may be, for example, 0.25 times or more as large as the depth (first depth B1) of recess 24. Third thickness B3 is not particularly limited, and may be, for example, 0.3 times or more as large as first depth B1, or may be 0.35 times or more as large as first depth B1. Third thickness B3 is not particularly limited, and may be, for example, 1 time or less as large as first depth B1 or 0.8 times or less as large as first depth B1.

### Second Embodiment

Next, a configuration of a semiconductor substrate 100 according to a second embodiment will be described. Semiconductor substrate 100 according to the second embodiment is different from semiconductor substrate 100 according to the first embodiment mainly in that epitaxial growth suppression film 30 is in contact with each of side surface 22 and bottom surface 23 of recess 24, and the other points are the same as those of semiconductor substrate 100 according to the first embodiment. Hereinafter, the configuration different from that of semiconductor substrate 100 according to the first embodiment will be mainly described.

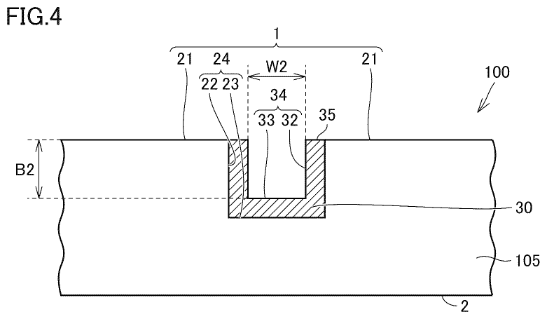

FIG. 4 is a schematic cross sectional view showing the configuration of semiconductor substrate 100 according to the second embodiment. As shown in FIG. 4, epitaxial growth suppression film 30 of semiconductor substrate 100 according to the second embodiment is in contact with each of side surface 22 and bottom surface 23 of recess 24. Epitaxial growth suppression film 30 may be formed along a whole of side surface 22. Epitaxial growth suppression film 30 may be in contact with the whole of side surface 22.

As shown in FIG. 4, a depression (first depression 34) may be formed by epitaxial growth suppression film 30. Specifically, epitaxial growth suppression film 30 has a second side surface 32, a second bottom surface 33, and a first top surface 35. Second side surface 32 is contiguous to second bottom surface 33. First top surface 35 is contiguous to second side surface 32. First top surface 35 may be formed along first flat surface 21.

First depression 34 is constituted of second side surface 32 and second bottom surface 33. Second side surface 32 faces first side surface 22. Second bottom surface 33 faces first bottom surface 23. The width (second width W2) of first depression 34 may be smaller than the width (first width W1) of recess 24. The depth (second depth B2) of first depression 34 may be smaller than the depth (first depth B1) of recess 24.

### Third Embodiment

Next, a configuration of a semiconductor substrate 100 according to a third embodiment will be described. Semiconductor substrate 100 according to the third embodiment is different from semiconductor substrate 100 according to the first embodiment mainly in that recess 24 is filled with epitaxial growth suppression film 30, and the other points are the same as those of semiconductor substrate 100 according to the first embodiment. Hereinafter, the configuration different from that of semiconductor substrate 100 according to the first embodiment will be mainly described.

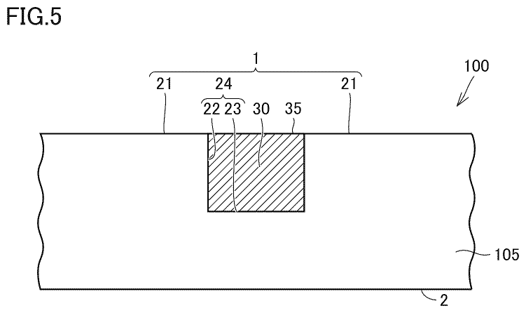

FIG. 5 is a schematic cross sectional view showing the configuration of semiconductor substrate 100 according to the third embodiment. As shown in FIG. 5, recess 24 may be filled with epitaxial growth suppression film 30. Epitaxial growth suppression film 30 is in contact with each of first side surface 22 and first bottom surface 23 of recess 24. Epitaxial growth suppression film 30 may completely fill recess 24. Epitaxial growth suppression film 30 has a first top surface 35. First top surface 35 may be formed along first flat surface 21.

### Fourth Embodiment

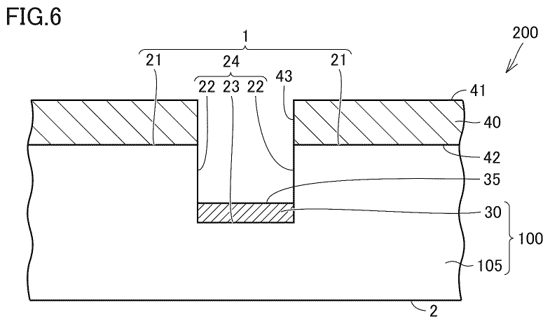

Next, a configuration of a semiconductor epitaxial substrate 200 according to a fourth embodiment will be described. FIG. 6 is a schematic cross sectional view showing the configuration of semiconductor epitaxial substrate 200 according to the fourth embodiment. As shown in FIG. 6, semiconductor epitaxial substrate 200 according to the fourth embodiment has: semiconductor substrate 100 according to the first embodiment; and an epitaxial layer 40. Epitaxial layer 40 is provided on at least a portion of first main surface 1 of semiconductor substrate 100.

Epitaxial layer 40 has a third main surface 41, a fourth main surface 42, and a third side surface 43. Fourth main surface 42 is located opposite to third main surface 41. Third side surface 43 is contiguous to each of third main surface 41 and fourth main surface 42. Fourth main surface 42 is in contact with first main surface 1.

Third side surface 43 may be formed along first side surface 22. Epitaxial layer 40 may be an epitaxial layer 40 having a homo-structure or an epitaxial layer 40 having a hetero-structure. Epitaxial layer 40 may be one layer or two or more layers.

In semiconductor epitaxial substrate 200 according to the fourth embodiment, epitaxial layer 40 is not formed on epitaxial growth suppression film 30. From another viewpoint, it can be said that epitaxial layer 40 is separated from epitaxial growth suppression film 30.

### Fifth Embodiment

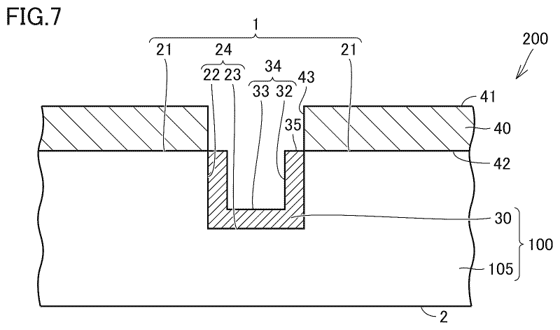

Next, a configuration of a semiconductor epitaxial substrate 200 according to a fifth embodiment will be described. FIG. 7 is a schematic cross sectional view showing the configuration of semiconductor epitaxial substrate 200 according to the fifth embodiment. As shown in FIG. 7, semiconductor epitaxial substrate 200 according to the fifth embodiment has: semiconductor substrate 100 according to the second embodiment; and an epitaxial layer 40. Epitaxial layer 40 is provided on at least a portion of first main surface 1 of semiconductor substrate 100.

Epitaxial layer 40 has a third main surface 41, a fourth main surface 42, and a third side surface 43. Fourth main surface 42 is located opposite to third main surface 41. Third side surface 43 is contiguous to each of third main surface 41 and fourth main surface 42. Fourth main surface 42 is in contact with first main surface 1. Third side surface 43 may be formed along first side surface 22. In semiconductor epitaxial substrate 200 according to the fifth embodiment, epitaxial layer 40 is not formed on epitaxial growth suppression film 30.

### Sixth Embodiment

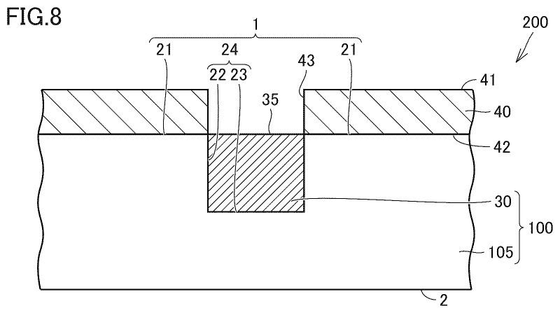

Next, a configuration of a semiconductor epitaxial substrate 200 according to a sixth embodiment will be described. FIG. 8 is a schematic cross sectional view showing the configuration of semiconductor epitaxial substrate 200 according to the sixth embodiment. As shown in FIG. 8, semiconductor epitaxial substrate 200 according to the sixth embodiment has: semiconductor substrate 100 according to the third embodiment; and an epitaxial layer 40. Epitaxial layer 40 is provided on at least a portion of first main surface 1 of semiconductor substrate 100.

Epitaxial layer 40 has a third main surface 41, a fourth main surface 42, and a third side surface 43. Fourth main surface 42 is located opposite to third main surface 41. Third side surface 43 is contiguous to each of third main surface 41 and fourth main surface 42. Fourth main surface 42 is in contact with first main surface 1.

Third side surface 43 may be formed along first side surface 22. In semiconductor epitaxial substrate 200 according to the sixth embodiment, epitaxial layer 40 is not formed on epitaxial growth suppression film 30.

### Seventh Embodiment

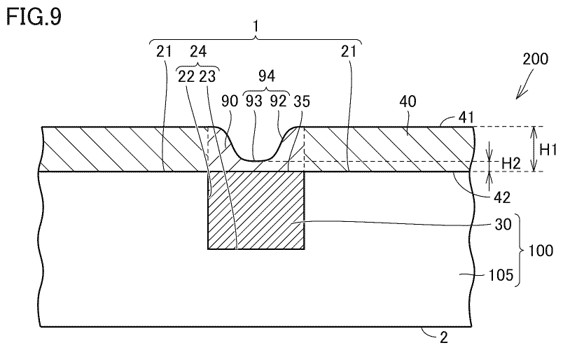

Next, a configuration of a semiconductor epitaxial substrate 200 according to a seventh embodiment will be described. FIG. 9 is a schematic cross sectional view showing the configuration of semiconductor epitaxial substrate 200 according to the seventh embodiment. As shown in FIG. 9, semiconductor epitaxial substrate 200 according to the seventh embodiment has: semiconductor substrate 100 according to the third embodiment; an epitaxial layer 40; and a semiconductor layer 90. Epitaxial layer 40 is provided on at least a portion of first main surface 1 of semiconductor substrate 100.

Epitaxial layer 40 has a third main surface 41 and a fourth main surface 42. Fourth main surface 42 is located opposite to third main surface 41. Fourth main surface 42 is in contact with first main surface 1.

Semiconductor layer 90 is formed on epitaxial growth suppression film 30. Semiconductor layer 90 is a layer formed with epitaxial growth being suppressed. Semiconductor layer 90 may be polycrystalline or amorphous, for example. The material of semiconductor layer 90 is the same as the material of epitaxial layer 40.

Semiconductor layer 90 may be contiguous to epitaxial layer 40. A thickness (first thickness H1) of epitaxial layer 40 may be larger than a minimum value (second thickness H2) of a thickness of semiconductor layer 90. Semiconductor layer 90 may be provided with a second depression 94. Second depression 94 is constituted of a fourth side surface 92 and a fourth bottom surface 93. Fourth bottom surface 93 is contiguous to fourth side surface 92. Fourth side surface 92 may be curved to protrude outward. Fourth side surface 92 may be contiguous to third main surface 41.

Although it has been described that semiconductor epitaxial substrate 200 according to the seventh embodiment has semiconductor substrate 100 according to the third embodiment, epitaxial layer 40, and semiconductor layer 90, the present disclosure is not limited to the configuration described above. Semiconductor epitaxial substrate 200 according to the seventh embodiment may have semiconductor substrate 100 according to the first embodiment, epitaxial layer 40, and semiconductor layer 90, or may have semiconductor substrate 100 according to the second embodiment, epitaxial layer 40, and semiconductor layer 90.

### Eighth Embodiment

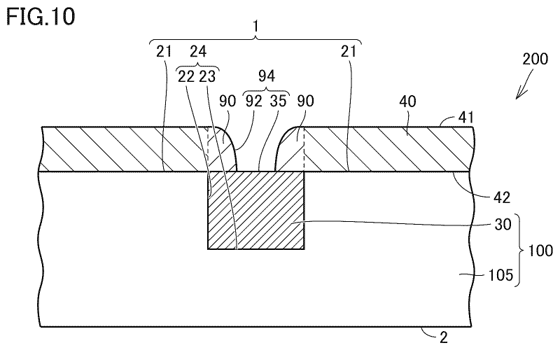

Next, a configuration of a semiconductor epitaxial substrate 200 according to an eighth embodiment will be described. Semiconductor epitaxial substrate 200 according to the eighth embodiment is different from semiconductor epitaxial substrate 200 according to the seventh embodiment mainly in that a portion of epitaxial growth suppression film 30 is exposed from semiconductor layer 90, and the other points are the same as those of semiconductor epitaxial substrate 200 according to the seventh embodiment. Hereinafter, the configuration different from that of semiconductor epitaxial substrate 200 according to the seventh embodiment will be mainly described. FIG. 10 is a schematic cross sectional view showing the configuration of semiconductor epitaxial substrate 200 according to the eighth embodiment. As shown in FIG. 10, a portion of epitaxial growth suppression film 30 is exposed from semiconductor layer 90. Second depression 94 is constituted of fourth side surface 92 and first top surface 35. Fourth side surface 92 is formed by semiconductor layer 90. First top surface 35 is formed by epitaxial growth suppression film 30.

### Ninth Embodiment

Next, a configuration of a semiconductor epitaxial substrate 200 according to a ninth embodiment will be described. Semiconductor epitaxial substrate 200 according to the ninth embodiment is different from semiconductor substrate 100 according to the first embodiment mainly in that reference mark 3 is formed in first epitaxial layer 71, and the other points are the same as those of semiconductor substrate 100 according to the first embodiment. Hereinafter, the configuration different from that of semiconductor substrate 100 according to the first embodiment will be mainly described.

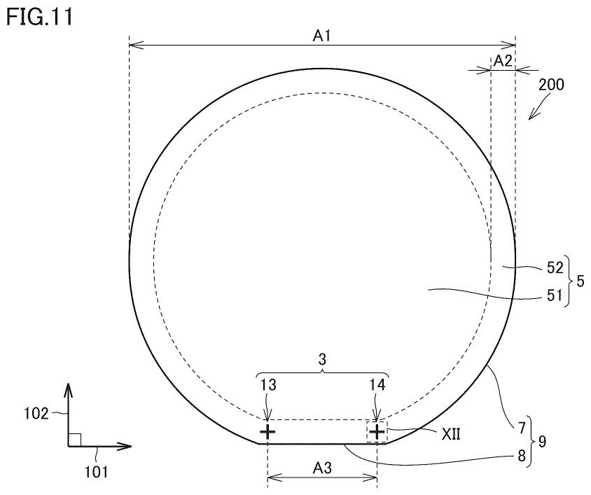

FIG. 11 is a schematic plan view showing the configuration of semiconductor epitaxial substrate 200 according to the ninth embodiment. As shown in FIG. 11, semiconductor epitaxial substrate 200 according to the ninth embodiment mainly has a fifth main surface 5 and outer peripheral edge 9. When viewed in a direction perpendicular to fifth main surface 5, fifth main surface 5 is surrounded by outer peripheral edge 9. Fifth main surface 5 is constituted of a second central region 51 and a second outer peripheral region 52. Second outer peripheral region 52 is a region within 5 mm from outer peripheral edge 9. Second central region 51 is surrounded by second outer peripheral region 52. In a radial direction of fifth main surface 5, a spacing A2 is 5 mm between outer peripheral edge 9 and a boundary between second central region 51 and second outer peripheral region 52.

As shown in FIG. 11, when viewed in the direction perpendicular to fifth main surface 5, fifth main surface 5 is expanded along each of first direction 101 and second direction 102. When viewed in the direction perpendicular to fifth main surface 5, second direction 102 is a direction perpendicular to first direction 101. A maximum diameter A1 of fifth main surface 5 is substantially the same as maximum diameter A1 of first main surface 1.

As shown in FIG. 11, semiconductor epitaxial substrate 200 has a reference mark 3. Reference mark 3 has at least two or more reference marks provided in fifth main surface 5. In second outer peripheral region 52, for example, two reference marks 3 are provided. Each of two or more reference marks 3 serves as a reference in two-dimensional position coordinates. As shown in FIG. 11, each of two or more reference marks 3 may be located in a region (second outer peripheral region 52) within 5 mm from orientation flat 8 when viewed in the direction perpendicular to fifth main surface 5.

Fifth main surface 5 may be the {0001} plane or a plane inclined with respect to the {0001} plane. When fifth main surface 5 is inclined with respect to the {0001} plane, an inclination angle (off angle) thereof with respect to the {0001} plane is, for example, 1° or more and 8° or less. When fifth main surface 5 is inclined with respect to the {0001} plane, an inclination direction (off direction) of fifth main surface 5 is, for example, the <11-20> direction.

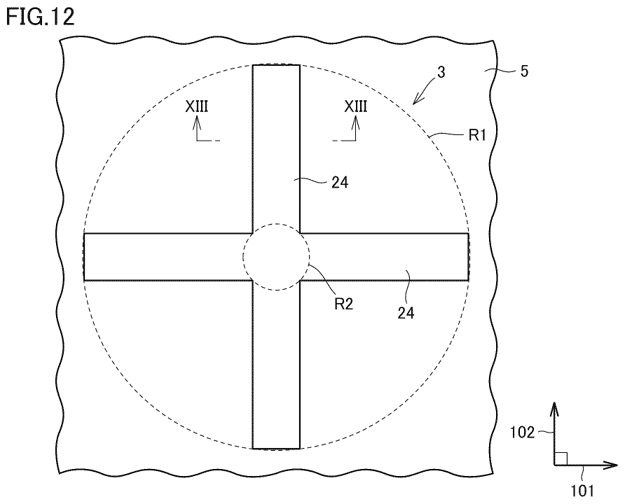

FIG. 12 is an enlarged plan view showing a region XII in FIG. 11. As shown in FIG. 12, reference mark 3 is constituted of a recess 24 formed in fifth main surface 5 and serves as a reference for an in-plane coordinate. When viewed in the direction perpendicular to fifth main surface 5, the shape of reference mark 3 is, for example, axisymmetric. The shape of reference mark 3 is, for example, a cross shape. For example, two recesses 24 may be provided to intersect perpendicularly at the center thereof. Reference mark 3 may be formed by a single recess 24, or may be formed by a plurality of recesses 24 such as a collection of processing marks.

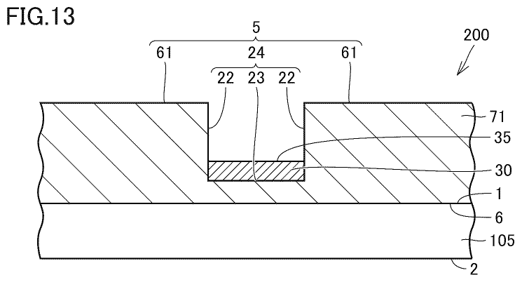

FIG. 13 is a schematic cross sectional view along a line XIII-XIII of FIG. 12. As shown in FIG. 13, semiconductor epitaxial substrate 200 according to the ninth embodiment has a semiconductor base material 105, a first epitaxial layer 71, and an epitaxial growth suppression film 30. Semiconductor base material 105 has first main surface 1 and second main surface 2. Second main surface 2 is located opposite to first main surface 1. First epitaxial layer 71 is provided on semiconductor base material 105. Fifth main surface 5 is formed by first epitaxial layer 71. First epitaxial layer 71 has a sixth main surface 6. Sixth main surface 6 is located opposite to fifth main surface 5. Sixth main surface 6 is in contact with first main surface 1.

Recess 24 is provided to be opened at fifth main surface 5. Recess 24 is constituted of a first side surface 22 and a first bottom surface 23. First bottom surface 23 is contiguous to first side surface 22. Fifth main surface 5 has a second flat surface 61. First side surface 22 is contiguous to second flat surface 61. Second flat surface 61 may be parallel to sixth main surface 6. In the thickness direction of semiconductor base material 105, first bottom surface 23 of recess 24 is located between second flat surface 61 and sixth main surface 6.

Semiconductor base material 105 is composed of a semiconductor material. Specific examples of the semiconductor material are as described above. Epitaxial growth suppression film 30 is composed of a material different from the semiconductor material of fifth main surface 5 of semiconductor base material 105. Specific examples of the material of epitaxial growth suppression film 30 are as described above.

Epitaxial growth suppression film 30 is provided in at least part of inside of recess 24. Epitaxial growth suppression film 30 is in contact with first bottom surface 23, for example. Epitaxial growth suppression film 30 may be in contact with a portion of first side surface 22. The configuration of each of recess 24 and epitaxial growth suppression film 30 is as described above.

### Tenth Embodiment

Next, a configuration of a semiconductor epitaxial substrate 200 according to a tenth embodiment will be described. Semiconductor epitaxial substrate 200 according to the tenth embodiment is different from semiconductor epitaxial substrate 200 according to the ninth embodiment mainly in that epitaxial growth suppression film 30 is in contact with each of side surface 22 and bottom surface 23 of recess 24, and the other points are the same as those of semiconductor epitaxial substrate 200 according to the ninth embodiment. Hereinafter, the configuration different from that of semiconductor epitaxial substrate 200 according to the ninth embodiment will be mainly described.

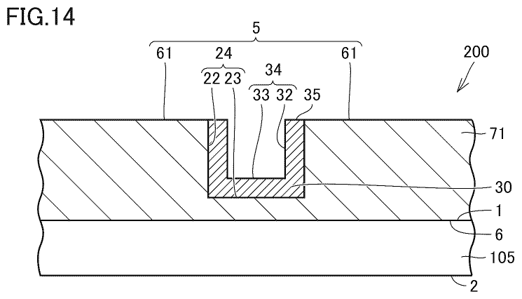

FIG. 14 is a schematic cross sectional view showing the configuration of semiconductor epitaxial substrate 200 according to the tenth embodiment. As shown in FIG. 14, epitaxial growth suppression film 30 of semiconductor epitaxial substrate 200 according to the tenth embodiment is in contact with each of first side surface 22 and first bottom surface 23 of recess 24. Epitaxial growth suppression film 30 may be formed along a whole of first side surface 22. Epitaxial growth suppression film 30 may be in contact with the whole of first side surface 22.

### Eleventh Embodiment

Next, a configuration of a semiconductor epitaxial substrate 200 according to an eleventh embodiment will be described. Semiconductor epitaxial substrate 200 according to the eleventh embodiment is different from semiconductor epitaxial substrate 200 according to the tenth embodiment mainly in that recess 24 is filled with epitaxial growth suppression film 30, and the other points are the same as those of semiconductor epitaxial substrate 200 according to the tenth embodiment. Hereinafter, the configuration different from that of semiconductor epitaxial substrate 200 according to the tenth embodiment will be mainly described.

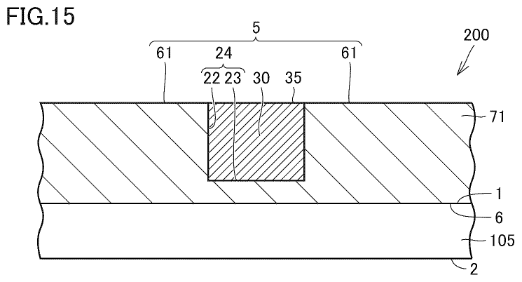

FIG. 15 is a schematic cross sectional view showing the configuration of semiconductor epitaxial substrate 200 according to the eleventh embodiment. As shown in FIG. 15, recess 24 may be filled with epitaxial growth suppression film 30. Epitaxial growth suppression film 30 is in contact with each of first side surface 22 and first bottom surface 23 of recess 24. Epitaxial growth suppression film 30 may completely fill recess 24. First top surface 35 of epitaxial growth suppression film 30 may be formed along second flat surface 61.

### Twelfth Embodiment

Next, a configuration of a semiconductor epitaxial substrate 200 according to a twelfth embodiment will be described. Semiconductor epitaxial substrate 200 according to the twelfth embodiment is different from semiconductor epitaxial substrate 200 according to the ninth embodiment mainly in that semiconductor epitaxial substrate 200 according to the twelfth embodiment has a second epitaxial layer 72, and the other points are the same as those of semiconductor epitaxial substrate 200 according to the ninth embodiment. Hereinafter, the configuration different from that of semiconductor epitaxial substrate 200 according to the ninth embodiment will be mainly described.

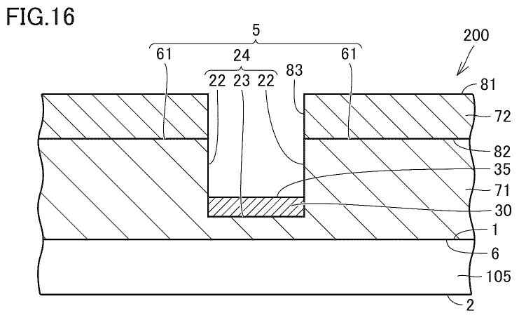

FIG. 16 is a schematic cross sectional view showing the configuration of semiconductor epitaxial substrate 200 according to the twelfth embodiment. As shown in FIG. 16, semiconductor epitaxial substrate 200 according to the twelfth embodiment further has second epitaxial layer 72. Second epitaxial layer 72 is provided on at least a portion of fifth main surface 5. As shown in FIG. 16, second epitaxial layer 72 may not be formed on epitaxial growth suppression film 30. From another viewpoint, it can be said that second epitaxial layer 72 may be separated from epitaxial growth suppression film 30.

### Thirteenth Embodiment

Next, a configuration of a semiconductor epitaxial substrate 200 according to a thirteenth embodiment will be described. Semiconductor epitaxial substrate 200 according to the thirteenth embodiment is different from semiconductor epitaxial substrate 200 according to the tenth embodiment mainly in that semiconductor epitaxial substrate 200 according to the thirteenth embodiment has a second epitaxial layer 72, and the other points are the same as those of semiconductor epitaxial substrate 200 according to the tenth embodiment. Hereinafter, the configuration different from that of semiconductor epitaxial substrate 200 according to the tenth embodiment will be mainly described.

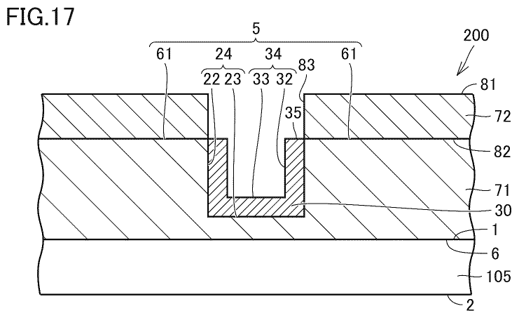

FIG. 17 is a schematic cross sectional view showing the configuration of semiconductor epitaxial substrate 200 according to the thirteenth embodiment. As shown in FIG. 17, semiconductor epitaxial substrate 200 according to the thirteenth embodiment further has second epitaxial layer 72. Second epitaxial layer 72 is provided on at least a portion of fifth main surface 5. As shown in FIG. 17, second epitaxial layer 72 may not be formed on epitaxial growth suppression film 30. From another viewpoint, it can be said that second epitaxial layer 72 may be separated from epitaxial growth suppression film 30.

### Fourteenth Embodiment

Next, a configuration of a semiconductor epitaxial substrate 200 according to a fourteenth embodiment will be described. Semiconductor epitaxial substrate 200 according to the fourteenth embodiment is different from semiconductor epitaxial substrate 200 according to the eleventh embodiment mainly in that semiconductor epitaxial substrate 200 according to the fourteenth embodiment has a second epitaxial layer 72, and the other points are the same as those of semiconductor epitaxial substrate 200 according to the eleventh embodiment. Hereinafter, the configuration different from that of semiconductor epitaxial substrate 200 according to the eleventh embodiment will be mainly described.

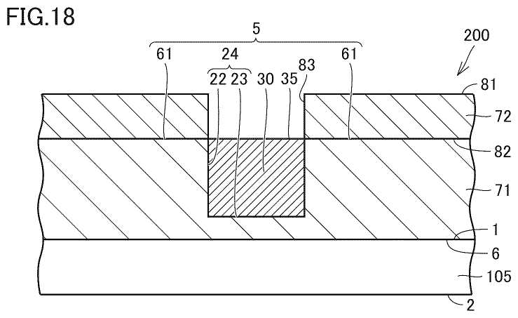

FIG. 18 is a schematic cross sectional view showing the configuration of semiconductor epitaxial substrate 200 according to the fourteenth embodiment. As shown in FIG. 18, semiconductor epitaxial substrate 200 according to the fourteenth embodiment further has second epitaxial layer 72. Second epitaxial layer 72 is provided on at least a portion of fifth main surface 5. As shown in FIG. 18, second epitaxial layer 72 may not be formed on epitaxial growth suppression film 30. From another viewpoint, it can be said that second epitaxial layer 72 may be separated from epitaxial growth suppression film 30.

### Fifteenth Embodiment

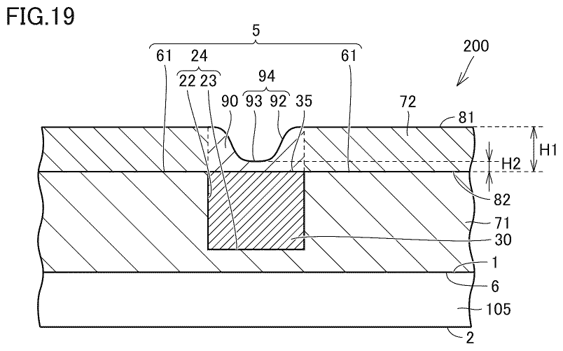

Next, a configuration of a semiconductor epitaxial substrate 200 according to a fifteenth embodiment will be described. FIG. 19 is a schematic cross sectional view showing the configuration of semiconductor epitaxial substrate 200 according to the fifteenth embodiment. As shown in FIG. 19, semiconductor epitaxial substrate 200 according to the fifteenth embodiment has: semiconductor epitaxial substrate 200 according to the eleventh embodiment; a second epitaxial layer 72; and a semiconductor layer 90. Second epitaxial layer 72 is provided on at least a portion of fifth main surface 5 of first epitaxial layer 71.

Second epitaxial layer 72 has a seventh main surface 81 and an eighth main surface 82. Eighth main surface 82 is located opposite to seventh main surface 81. Eighth main surface 82 is in contact with fifth main surface 5.

Semiconductor layer 90 is formed on epitaxial growth suppression film 30. Semiconductor layer 90 is a layer formed with epitaxial growth being suppressed. Semiconductor layer 90 may be polycrystalline or amorphous, for example. The material of semiconductor layer 90 is the same as the material of epitaxial layer 40.

Semiconductor layer 90 may be contiguous to second epitaxial layer 72. A thickness (first thickness H1) of second epitaxial layer 72 may be larger than a minimum value (second thickness H2) of the thickness of semiconductor layer 90. Semiconductor layer 90 may be provided with a second depression 94. Second depression 94 is constituted of a fourth side surface 92 and a fourth bottom surface 93. Fourth bottom surface 93 is contiguous to fourth side surface 92. Fourth side surface 92 may be curved to protrude outward. Fourth side surface 92 may be contiguous to seventh main surface 81.

Although it has been described that semiconductor epitaxial substrate 200 according to the fifteenth embodiment has semiconductor epitaxial substrate 200 according to the eleventh embodiment, second epitaxial layer 72, and semiconductor layer 90, the present disclosure is not limited to the configuration described above. Semiconductor epitaxial substrate 200 according to the fifteenth embodiment may have semiconductor epitaxial substrate 200 according to the twelfth embodiment, second epitaxial layer 72, and semiconductor layer 90, or may have semiconductor epitaxial substrate 200 according to the thirteenth embodiment, second epitaxial layer 72, and semiconductor layer 90.

### Sixteenth Embodiment

Next, a configuration of a semiconductor epitaxial substrate 200 according to a sixteenth embodiment will be described. Semiconductor epitaxial substrate 200 according to the sixteenth embodiment is different from semiconductor epitaxial substrate 200 according to the fifteenth embodiment mainly in that a portion of epitaxial growth suppression film 30 is exposed from semiconductor layer 90, and the other points are the same as those of semiconductor epitaxial substrate 200 according to the fifteenth embodiment. Hereinafter, the configuration different from that of semiconductor epitaxial substrate 200 according to the fifteenth embodiment will be mainly described.

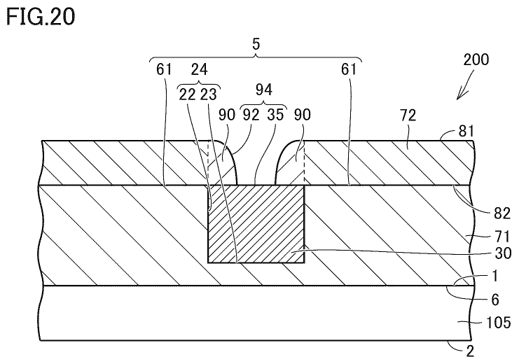

FIG. 20 is a schematic cross sectional view showing the configuration of semiconductor epitaxial substrate 200 according to the sixteenth embodiment. As shown in FIG. 20, a portion of epitaxial growth suppression film 30 is exposed from semiconductor layer 90. A second depression 94 is constituted of a fourth side surface 92 and a first top surface 35. Fourth side surface 92 is formed by semiconductor layer 90. First top surface 35 is formed by epitaxial growth suppression film 30.

### Method of Manufacturing Semiconductor Substrate

Next, a first method of manufacturing semiconductor substrate 100 according to the second embodiment will be described.

### Lift-Off Technique

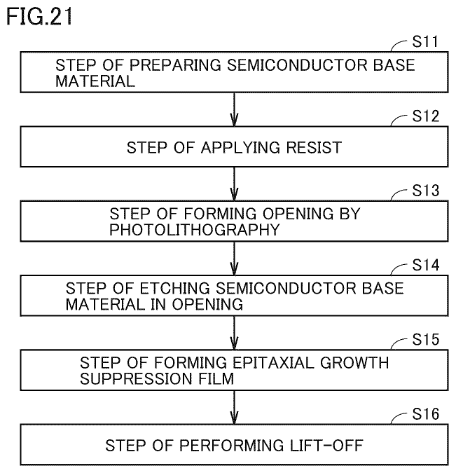

FIG. 21 is a flowchart schematically showing the first method of manufacturing semiconductor substrate 100 according to the second embodiment. As shown in FIG. 21, the first method of manufacturing semiconductor substrate 100 according to the second embodiment mainly has: a step (S11) of preparing semiconductor base material 105; a step (S12) of applying a resist; a step (S13) of forming an opening by photolithography; a step (S14) of etching semiconductor base material 105 in the opening; a step (S15) of forming epitaxial growth suppression film 30; and a step (S16) of performing lift-off.

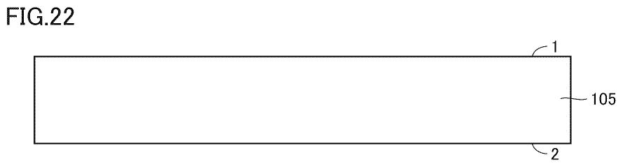

First, the step (S11) of preparing semiconductor base material 105 is performed. For example, a silicon carbide single crystal having a polytype of 4H is produced by a sublimation method. Next, the silicon carbide single crystal is sliced by, for example, a wire saw, thereby preparing semiconductor base material 105. FIG. 22 is a schematic cross sectional view showing the step of preparing the semiconductor base material. As shown in FIG. 22, semiconductor base material 105 has first main surface 1 and second main surface 2. Second main surface 2 is located opposite to first main surface 1. After slicing semiconductor base material 105, first main surface 1 or second main surface 2 may be polished, or semiconductor base material 105 may be cleaned.

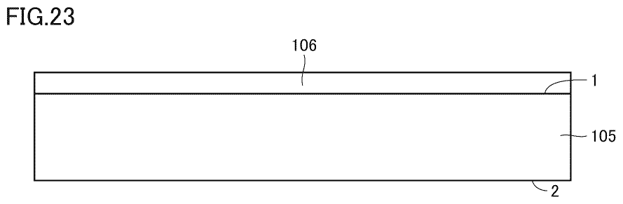

Next, the step (S12) of applying a resist is performed. FIG. 23 is a schematic sectional view showing the step of applying a resist. As shown in FIG. 23, a resist layer 106 is applied onto semiconductor base material 105. Resist layer 106 is formed on first main surface 1 of semiconductor base material 105.

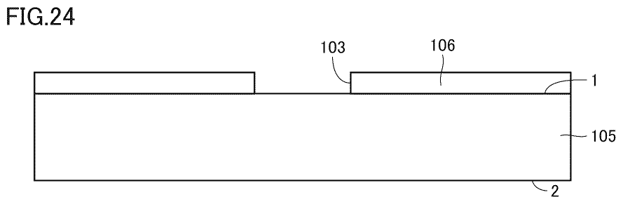

Next, the step (S13) of forming an opening by photolithography is performed. FIG. 24 is a schematic cross sectional view showing the step of forming an opening by photolithography. As shown in FIG. 24, an opening 103 is formed in resist layer 106 by using a photolithography method. A portion of first main surface 1 of semiconductor base material 105 is exposed in opening 103 formed in resist layer 106.

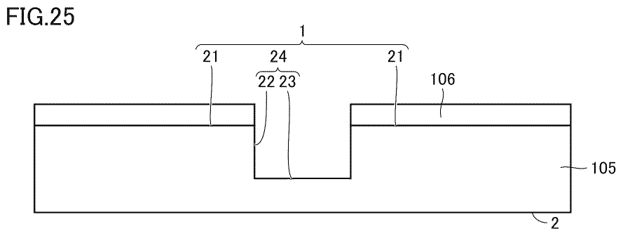

Next, the step (S14) of etching semiconductor base material 105 in opening 103 is performed. FIG. 25 is a schematic cross sectional view showing the step of etching the semiconductor base material in opening 103. As shown in FIG. 25, by using an etching method, a portion of semiconductor base material 105 is etched in opening 103. Thus, recess 24 is formed in first main surface 1 of semiconductor base material 105. Recess 24 is formed to be opened at first main surface 1. Recess 24 is constituted of first side surface 22 and first bottom surface 23. First bottom surface 23 is contiguous to first side surface 22.

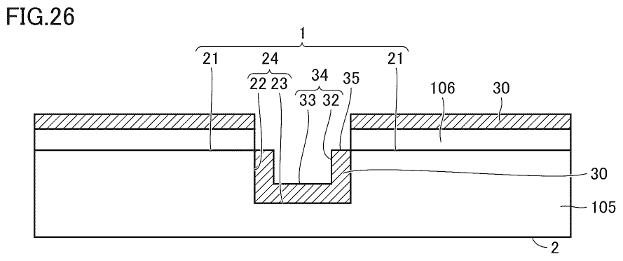

Next, the step (S15) of forming epitaxial growth suppression film 30 is performed. FIG. 26 is a first schematic cross sectional view showing the step of forming epitaxial growth suppression film 30. As shown in FIG. 26, epitaxial growth suppression film 30 is formed on semiconductor base material 105. Epitaxial growth suppression film 30 is formed on resist layer 106 and is formed inside recess 24. Epitaxial growth suppression film 30 may be formed in contact with each of first side surface 22 and first bottom surface 23.

A method of forming epitaxial growth suppression film 30 is a physical vapor deposition (PVD) method such as a vacuum deposition method, a sputtering method, or an ion plating method, or is a chemical vapor deposition (CVD) method. From the viewpoint of improving a filling property of epitaxial growth suppression film 30, the ion plating method, which allows for high adhesion, or the chemical vapor deposition (CVD) method, which allows for high coverage or adhesion even under presence of irregularities, are desirably used among the above-described forming methods. The above-described method of forming epitaxial growth suppression film 30 is also applicable to each of a polishing method 1 and a polishing method 2, which will be described later.

Next, the step (S16) of performing lift-off is performed. In the step (S16) of performing lift-off, resist layer 106 is removed from semiconductor base material 105 by lift-off. Epitaxial growth suppression film 30 formed on resist layer 106 is removed together with resist layer 106. Epitaxial growth suppression film 30 formed in recess 24 is left in recess 24. In this way, semiconductor substrate 100 according to the second embodiment is manufactured (see FIG. 4).

Next, a second method of manufacturing semiconductor substrate 100 according to the second embodiment will be described.

### Polishing Method 1

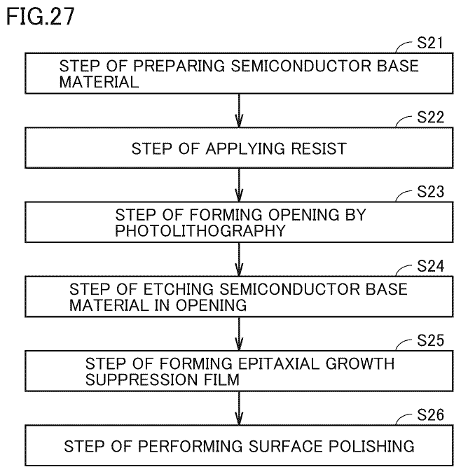

FIG. 27 is a flowchart schematically showing the second method of manufacturing semiconductor substrate 100 according to the second embodiment. As shown in FIG. 27, the second method of manufacturing semiconductor substrate 100 according to the second embodiment mainly has: a step (S21) of preparing a semiconductor base material 105; a step (S22) of applying a resist; a step (S23) of forming opening 103 by photolithography; a step (S24) of etching semiconductor base material 105 in opening 103; a step (S25) of forming epitaxial growth suppression film 30; and a step (S26) of performing surface polishing.

First, the step (S21) of preparing semiconductor base material 105 is performed. After slicing semiconductor base material 105, first main surface 1 or second main surface 2 may be polished, or semiconductor base material 105 may be cleaned. The step (S21) of preparing semiconductor base material 105 in the second method of manufacturing is the same as the step (S11) of preparing semiconductor base material 105 in the first method of manufacturing (see FIG. 22). Next, the step (S22) of applying a resist is performed. The step (S22) of applying a resist in the second method of manufacturing is the same as the step (S12) of applying the resist in the first method of manufacturing (see FIG. 23).

Next, the step (S23) of forming opening 103 by photolithography is performed. The step (S23) of forming opening 103 by photolithography in the second method of manufacturing is the same as the step (S13) of forming opening 103 by photolithography in the first method of manufacturing (see FIG. 24). Next, the step (S24) of etching semiconductor base material 105 in opening 103 is performed. The step (S24) of etching semiconductor base material 105 in opening 103 in the second method of manufacturing is the same as the step (S14) of etching semiconductor base material 105 in opening 103 in the first method of manufacturing (see FIG. 25). After recess 24 is formed in first main surface 1 by etching semiconductor base material 105, resist layer 106 is removed from first main surface 1.

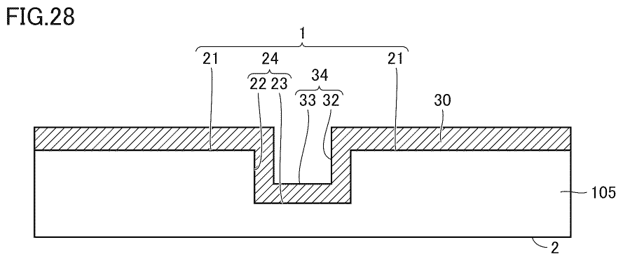

Next, the step (S25) of forming epitaxial growth suppression film 30 is performed. FIG. 28 is a second schematic cross sectional view showing the step of forming epitaxial growth suppression film 30. As shown in FIG. 28, epitaxial growth suppression film 30 is formed on semiconductor base material 105. Epitaxial growth suppression film 30 is formed on first main surface 1. Specifically, epitaxial growth suppression film 30 is formed in contact with each of first flat surface 21, first side surface 22, and first bottom surface 23.

Next, the step (S26) of performing surface polishing is performed. In the step (S26) of performing surface polishing, polishing is performed onto a portion of epitaxial growth suppression film 30. Thus, the portion of epitaxial growth suppression film 30 formed on first flat surface 21 is removed. Epitaxial growth suppression film 30 formed in recess 24 is left in recess 24. In this way, semiconductor substrate 100 according to the second embodiment is manufactured (see FIG. 4).

Next, a third method of manufacturing semiconductor substrate 100 according to the second embodiment will be described.

### Polishing Method 2

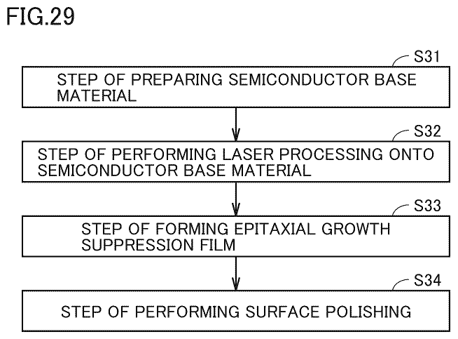

FIG. 29 is a flowchart schematically showing the third method of manufacturing semiconductor substrate 100 according to the second embodiment. As shown in FIG. 29, the third method of manufacturing semiconductor substrate 100 according to the second embodiment mainly has: a step (S31) of preparing semiconductor base material 105; a step (S32) of performing laser processing onto semiconductor base material 105; a step (S33) of forming epitaxial growth suppression film 30; and a step (S34) of performing surface polishing.

First, the step (S31) of preparing semiconductor base material 105 is performed. After slicing semiconductor base material 105, first main surface 1 or second main surface 2 may be polished, or semiconductor base material 105 may be cleaned. The step (S31) of preparing semiconductor base material 105 in the third method of manufacturing is the same as the step (S11) of preparing semiconductor base material 105 in the first method of manufacturing (see FIG. 22).

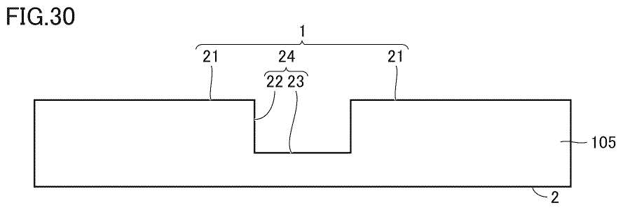

Next, the step (S32) of performing laser processing onto semiconductor base material 105 is performed. FIG. 30 is a schematic cross sectional view showing the step of performing laser processing onto the semiconductor base material. As shown in FIG. 30, a portion of semiconductor base material 105 is removed by performing laser processing onto semiconductor base material 105. Thus, recess 24 is formed in first main surface 1 of semiconductor base material 105. Recess 24 is formed to be opened at first main surface 1. Recess 24 is constituted of first side surface 22 and first bottom surface 23. First bottom surface 23 is contiguous to first side surface 22.

Next, the step (S33) of forming epitaxial growth suppression film 30 is performed. The step (S33) of forming epitaxial growth suppression film 30 in the third method of manufacturing is the same as the step (S25) of forming epitaxial growth suppression film 30 in the second method of manufacturing (see FIG. 28).

Next, the step (S34) of performing surface polishing is performed. The step (S34) of performing the surface polishing in the third method of manufacturing is the same as the step (S26) of performing the surface polishing in the second method of manufacturing. In this way, semiconductor substrate 100 according to the second embodiment is manufactured (see FIG. 4).

Next, a fourth method of manufacturing semiconductor substrate 100 according to the second embodiment will be described.

### Polishing Method 3

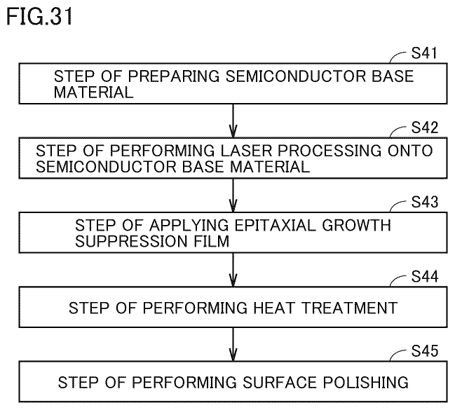

FIG. 31 is a flowchart schematically showing the fourth method of manufacturing semiconductor substrate 100 according to the second embodiment. As shown in FIG. 31, the fourth method of manufacturing semiconductor substrate 100 according to the second embodiment mainly has: a step (S41) of preparing semiconductor base material 105; a step (S42) of performing laser processing onto semiconductor base material 105; a step (S43) of forming epitaxial growth suppression film 30; a step (S44) of performing heat treatment; and a step (S45) of performing surface polishing.

First, the step (S41) of preparing semiconductor base material 105 is performed. After slicing semiconductor base material 105, first main surface 1 or second main surface 2 may be polished, or semiconductor base material 105 may be cleaned. The step (S41) of preparing semiconductor base material 105 in the fourth method of manufacturing is the same as the step (S11) of preparing semiconductor base material 105 in the first method of manufacturing (see FIG. 22). Next, the step (S42) of performing laser processing onto semiconductor base material 105 is performed. The step (S42) of performing laser processing onto semiconductor base material 105 in the fourth method of manufacturing is the same as the step (S32) of performing laser processing onto semiconductor base material 105 in the third method of manufacturing (see FIG. 30).

Next, the step (S43) of applying epitaxial growth suppression film 30 is performed. First, a spin coater is used to apply, onto first main surface 1 of semiconductor base material 105, a coating liquid obtained by dissolving the material of epitaxial growth suppression film 30 in a solvent. By rotating semiconductor base material 105, the coating liquid is expanded on first main surface 1 by centrifugal force. The coating liquid may be applied to a whole of first main surface 1, or may be applied to only a portion thereof having been through the laser processing. Further, the application method is not particularly limited. The application method may be a method using a dispenser or may be a method using an inkjet technique.

Next, the step (S44) of performing heat treatment is performed. Specifically, the solvent included in epitaxial growth suppression film 30 is evaporated by heating epitaxial growth suppression film 30. In this way, the solvent is removed from epitaxial growth suppression film 30, thereby solidifying epitaxial growth suppression film 30.

Next, the step (S45) of performing surface polishing is performed. The step (S45) of performing surface polishing in the fourth method of manufacturing is the same as the step (S26) of performing surface polishing in the second method of manufacturing. In this way, semiconductor substrate 100 according to the second embodiment is manufactured (see FIG. 4).

Next, functions and effects of semiconductor substrates 100 and semiconductor epitaxial substrates 200 according to the above-described embodiments will be described.

For example, a defect resulting from a material is a non-conforming factor for an element using a semiconductor material such as silicon carbide. Examples of the defect resulting from a material include: a defect caused in epitaxial layer 40, which is an active region of the element; and a defect caused in semiconductor base material 105, which is a base substrate for epitaxial layer 40. If the coordinates of the position of the defect in the wafer plane are known in advance, elements can be divided into a non-conforming product and a conforming product in advance. Further, by presuming a non-conforming ratio of the elements in advance, an element structure or an element arrangement can be optimally designed.

In order to associate the plane coordinates of the defect with the plane coordinates of the element, it is effective to provide the substrate with reference mark 3 serving as a reference for the plane coordinates in advance. Thus, a non-conforming product of an element due to the defect can be accurately specified. Reference mark 3 in the form of a recess can be formed by laser processing or etching processing. However, when epitaxial layer 40 is formed on semiconductor base material 105 in which reference mark 3 in the form of a recess is formed, epitaxial layer 40 is also formed inside reference mark 3 in the form of a recess, with the result that a portion of reference mark 3 in the form of a recess is buried in epitaxial layer 40. Thus, visibility of reference mark 3 is deteriorated. Accordingly, it is difficult to accurately associate the plane coordinates of the defect with the plane coordinates of the element.

In semiconductor substrate 100 or semiconductor epitaxial substrate 200 according to the present disclosure, epitaxial growth suppression film 30 is provided in at least part of inside of recess 24 constituting reference mark 3. Thus, epitaxial layer 40 can be suppressed from growing in recess 24 constituting reference mark 3. As a result, it is possible to suppress deterioration in visibility of reference mark 3 after epitaxial growth.

In semiconductor substrate 100 or semiconductor epitaxial substrate 200 according to the present disclosure, the depth of recess 24 may be more than 0.5 μm and less than 100 μm. Thus, it is possible to further suppress deterioration in visibility of reference mark 3.

In semiconductor substrate 100 or semiconductor epitaxial substrate 200 according to the present disclosure, recess 24 may be constituted of side surface 22 and bottom surface 23 contiguous to side surface 22. Epitaxial growth suppression film 30 may be in contact with bottom surface 23. Thus, epitaxial layer 40 can be suppressed from growing on bottom surface 23 of recess 24.

In semiconductor substrate 100 or semiconductor epitaxial substrate 200 according to the present disclosure, recess 24 may be constituted of side surface 22 and bottom surface 23 contiguous to side surface 22. Epitaxial growth suppression film 30 may be in contact with each of side surface 22 and bottom surface 23. The depression may be formed by epitaxial growth suppression film 30. Thus, epitaxial layer 40 can be suppressed from growing on each of bottom surface 23 and side surface 22 of recess 24.

In semiconductor substrate 100 or semiconductor epitaxial substrate 200 according to the present disclosure, recess 24 may be filled with epitaxial growth suppression film 30. Epitaxial layer 40 can be suppressed from growing above recess 24.

In semiconductor substrate 100 or semiconductor epitaxial substrate 200 according to the present disclosure, epitaxial growth suppression film 30 may be composed of a material including boron, carbon, nitrogen, or oxygen and having a melting point of 1700° C. or more. Thus, it is possible to suppress decomposition of epitaxial growth suppression film 30 in the temperature range in which epitaxial layer 40 is formed.

In semiconductor substrate 100 or semiconductor epitaxial substrate 200 according to the present disclosure, epitaxial growth suppression film 30 may be composed of a material including titanium, zirconium, hafnium, vanadium, niobium, tantalum, chromium, molybdenum, tungsten, magnesium, yttrium, aluminum, nickel, zinc, or gallium. Thus, it is possible to suppress decomposition of epitaxial growth suppression film 30 in the temperature range in which epitaxial layer 40 is formed.

In semiconductor substrate 100 or semiconductor epitaxial substrate 200 according to the present disclosure, the semiconductor material may be silicon carbide. Thus, it is possible to suppress deterioration of visibility particularly in a process of manufacturing a silicon carbide semiconductor device using each of a silicon carbide substrate and a silicon carbide epitaxial substrate.

In semiconductor substrate 100 or semiconductor epitaxial substrate 200 according to the present disclosure, the thickness of epitaxial growth suppression film 30 may be 0.25 times or more as large as the depth of recess 24. Thus, it is possible to more securely suppress deterioration in visibility of reference mark 3.

The embodiments disclosed herein are illustrative and non-restrictive in any respect. The scope of the present invention is defined by the terms of the claims, rather than the embodiments described above, and is intended to include any modifications within the scope and meaning equivalent to the terms of the claims.

### REFERENCE SIGNS LIST

1: first main surface (main surface); 2: second main surface; 3: reference mark; 5: fifth main surface (main surface); 6: sixth main surface; 7: arc-shaped portion; 8: orientation flat; 9: outer peripheral edge; 11: first central region; 12: first outer peripheral region; 13: first reference mark; 14: second reference mark; 21: first flat surface; 22: first side surface (side surface); 23: first bottom surface (bottom surface); 24: recess; 30: epitaxial growth suppression film; 32: second side surface; 33: second bottom surface; 34: first depression; 35: first top surface; 40: epitaxial layer; 41: third main surface; 42: fourth main surface; 43: third side surface; 51: second central region; 52: second outer peripheral region; 61: second flat surface; 71: first epitaxial layer; 72: second epitaxial layer; 81: seventh main surface; 82: eighth main surface; 83: fifth side surface; 90: semiconductor layer; 92: fourth side surface; 93: fourth bottom surface; 94: second depression; 100: semiconductor substrate; 101: first direction; 102: second direction; 103: opening; 105: semiconductor base material; 106: resist layer; 200: semiconductor epitaxial substrate; A1: maximum diameter; A2: spacing; A3: distance; B1: first depth; B2: second depth; B3: third thickness; H1: first thickness; H2: second thickness; R1: first imaginary circle; R2: second imaginary circle; W1: first width; W2: second width.

1. A semiconductor substrate comprising:
a main surface;
a reference mark that is constituted of a recess formed in the main surface and that serves as a reference for an in-plane coordinate; and
an epitaxial growth suppression film provided in at least part of inside of the recess, wherein
the reference mark has at least two or more reference marks provided in the main surface,
the main surface is composed of a semiconductor material, and
the epitaxial growth suppression film is composed of a material different from the semiconductor material.

2. The semiconductor substrate according to claim 1, wherein a depth of the recess is more than 0.5 μm and less than 100 μm.

3. The semiconductor substrate according to claim 1, wherein
the recess is constituted of a side surface and a bottom surface contiguous to the side surface, and
the epitaxial growth suppression film is in contact with the bottom surface.

4. The semiconductor substrate according to claim 1, wherein
the recess is constituted of a side surface and a bottom surface contiguous to the side surface,
the epitaxial growth suppression film is in contact with each of the side surface and the bottom surface, and
a depression is formed by the epitaxial growth suppression film.

5. The semiconductor substrate according to claim 1, wherein the recess is filled with the epitaxial growth suppression film.

6. The semiconductor substrate according to claim 1, wherein the epitaxial growth suppression film is composed of a material including boron, carbon, nitrogen or oxygen and having a melting point of 1700° C. or more.

7. The semiconductor substrate according to claim 1, wherein the epitaxial growth suppression film is composed of a material including titanium, zirconium, hafnium, vanadium, niobium, tantalum, chromium, molybdenum, tungsten, magnesium, yttrium, aluminum, nickel, zinc, or gallium.

8. The semiconductor substrate according to claim 1, wherein the semiconductor material is silicon carbide.

9. The semiconductor substrate according to claim 1, wherein a thickness of the epitaxial growth suppression film is 0.25 times or more as large as a depth of the recess.

10. A semiconductor epitaxial substrate comprising:
the semiconductor substrate according to claim 1;
a semiconductor layer formed on the epitaxial growth suppression film; and
an epitaxial layer provided on at least a portion of the main surface, wherein
a thickness of the epitaxial layer is larger than a minimum value of a thickness of the semiconductor layer.

11. A semiconductor epitaxial substrate comprising:
the semiconductor substrate according to claim 1; and
an epitaxial layer provided on at least a portion of the main surface, wherein
the epitaxial layer is not formed on the epitaxial growth suppression film.

12. A semiconductor epitaxial substrate comprising:
a semiconductor base material;
a first epitaxial layer provided on the semiconductor base material;
a main surface formed by the first epitaxial layer;
a reference mark that is constituted of a recess formed in the main surface and that serves as a reference for an in-plane coordinate; and
an epitaxial growth suppression film provided in at least part of inside of the recess, wherein
the reference mark has at least two or more reference marks provided in the main surface,
the main surface is composed of a semiconductor material, and
the epitaxial growth suppression film is composed of a material different from the semiconductor material.

13. The semiconductor epitaxial substrate according to claim 12, comprising:
a semiconductor layer formed on the epitaxial growth suppression film; and
a second epitaxial layer provided on at least a portion of the main surface, wherein
a thickness of the second epitaxial layer is larger than a minimum value of a thickness of the semiconductor layer.

14. The semiconductor epitaxial substrate according to claim 12, comprising a second epitaxial layer provided on at least a portion of the main surface, wherein
the second epitaxial layer is not formed on the epitaxial growth suppression film.
